(19) United States
(12) Patent Application Publication
(10) Pub. No.: US 2026/0301798 A1
(43) Pub. Date: Oct. 1, 2026

(54) DATA READ-WRITE CIRCUIT AND METHOD THEREFOR, MEMORY AND DRIVING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Zhengyong ZHU, Beijing (CN); Bok Moon KANG, Beijing (CN); Chao ZHAO, Beijing (CN)

(21) Appl. No.: 19/475,957

(22) PCT Filed: Oct. 26, 2023
(86) PCT No.: PCT/CN2023/126717

§ 371 Date: Oct. 16, 2025

(30) Foreign Application Priority Data
Apr. 28, 2023 (CN) 202310480552.6

(51) Int. Cl. G11C 11/4096; G11C 11/405

(52) U.S. Cl. CPC G11C 11/4096; G11C 11/405

(57) ABSTRACT

The present disclosure relates to the technical field of storage, and relates to a data read-write circuit and a method therefor, a memory and a driving method therefor, and an electronic device, which are used for improving the accuracy of data reading. The data read-write method comprises: in a pre-charging stage, a data signal line (BL1) provides a first reference voltage (v1) to a first transistor (T1), an auxiliary signal line (BL2) simultaneously provides the first reference voltage (v1) to the first transistor (T1) and a second transistor (T2), a first write control voltage (V_{CW1}) is applied to a second electrode (B) of a capacitor (C), the second transistor (T2) is turned on, and a memory node (SN) is pre-charged, the sum of a maximum data voltage corresponding to data and a threshold voltage of the first transistor (T1) being a reference voltage, and the first reference voltage (v1) being greater than the reference voltage; and in a data write stage, in response to a write command, the auxiliary signal line (BL2) floats, the data signal line (BL1) provides a data voltage to the first transistor (T1), the first transistor (T1) is turned on, the memory node (SN) is discharged to a stable state, and data corresponding to the data voltage is written.

### CROSS-REFERENCE TO RELATED APPLICATIONS

The present disclosure is a national stage of International Application No. PCT/CN2023/126717 filed on Oct. 26, 2023, which claims priority to Chinese Patent Application No. 202310480552.6, filed to the China National Intellectual Property Administration on Apr. 28, 2023, and entitled “DATA READ-WRITE CIRCUIT AND METHOD THEREFOR, MEMORY AND DRIVING METHOD THEREFOR, AND ELECTRONIC DEVICE”. The disclosures of International Application No. PCT/CN2023/126717 and Chinese Patent Application No. 202310480552.6 are hereby incorporated by reference in their entireties.

### TECHNICAL FIELD

The present disclosure relates to the field of storage technologies, and in particular, to a circuit for reading and writing data, a method for reading and writing data, a memory, a method for driving a memory, and an electronic device.

### BACKGROUND

With the developments of communication technology and digital technology, there is a continuous pursuit for products with lower power consumption, lighter weight, and better performance. Memories tend to have higher integration density and larger storage capacity, and gradually become one of the important research directions in the current storage field. For example, in three-dimensional dynamic random-access memory, compared to a memory cell adopting a 1T1C architecture, a problem of difficult capacitor fabrication processes caused by shrinking critical dimensions when the memory cell adopts the 1T1C architecture can be effectively solved by a memory cell adopting a 2T architecture.

### SUMMARY

According to some embodiments, an aspect of the present disclosure provides a method for reading and writing data applied to a memory cell. The memory cell is configured to store data and includes a capacitor, the first transistor and the second transistor that are connected with the first electrode of the capacitor. An intersection point where the first electrode of the capacitor, the first transistor, and the second transistor are connected with each other is a storage node. The capacitor further includes the second electrode disposed opposite to the first electrode. A data read-write period of the memory cell includes: a precharging stage and a data writing stage. The method for reading and writing data includes the following operations.

In the precharging stage, a data signal line supplies the first reference voltage to the first transistor, and an auxiliary signal line simultaneously supplies the first reference voltage to both the first transistor and the second transistor. The first write control voltage is applied to the second electrode of the capacitor, and the second transistor is turned on to precharge the storage node. A sum of a maximum data voltage corresponding to the data and a threshold voltage of the first transistor is a benchmark voltage, and the first reference voltage is greater than the benchmark voltage.

In the data writing stage, in response to a write command, the auxiliary signal line is floated, the data signal line supplies a data voltage to the first transistor, and the first transistor is turned on. When the storage node is discharged to a stable state data corresponding to the data voltage is written into the storage node.

According to some embodiments, the data read-write period further includes: a data holding stage after the data writing stage. The method for reading and writing data further includes the following operations. In the data holding stage, a voltage of the data signal line is pulled up to the first reference voltage, and after the voltage of the data signal line is the first reference voltage, the second transistor is firstly turned off, and then a voltage of the auxiliary signal line is pulled up to the first reference voltage. After the second transistor is turned off, the second write control voltage is applied to the second electrode of the capacitor. The second write control voltage is less than the first write control voltage.

According to some other embodiments, the data read-write period further includes: a data holding stage after the data writing stage. The method for reading and writing data further includes the following operation. In the data holding stage, firstly the second write control voltage is applied to the second electrode of the capacitor, and a voltage of the data signal line is pulled up to the first reference voltage, and then the second transistor is turned off, and a voltage of the auxiliary signal line is pulled up to the first reference voltage. The second write control voltage is less than the first write control voltage.

According to some embodiments, the data read-write period further includes a data reading stage. The method for reading and writing data further includes the following operation. In the data reading stage, in response to a read command, a read control voltage is applied to the second electrode of the capacitor, and the auxiliary signal line supplies simultaneously the second reference voltage to both the first transistor and the second transistor. The data signal line reads data in response to whether the first transistor is turned on.

According to some embodiments, the data written into the storage node includes “1” or “0”. In the data reading stage, when the data written into the storage node is “1”, the first transistor is in an on state, and when the data written into the storage node is “0”, the first transistor is in an off state.

According to some embodiments, the data read-write period further includes: a standby stage before the precharging stage and/or before a data reading stage. The method for reading and writing data further includes the following operation. In the standby stage, the first transistor and the second transistor are in an off state, the data signal line supplies the first reference voltage to the first transistor, and the auxiliary signal line simultaneously supplies the first reference voltage to both the first transistor and the second transistor.

According to some embodiments, the data read-write period further includes: a data holding stage after the data writing stage. The data reading stage is after the data holding stage. The standby stage includes: the first standby stage before the precharging stage, and the second standby stage that is after the data holding stage and before the data reading stage.

According to some embodiments, another aspect of the present disclosure further provides a circuit for reading and writing data. The circuit for reading and writing data includes a memory cell, a data signal line, and an auxiliary signal line. The memory cell is configured to store data and includes a capacitor, and the first transistor and the second transistor that are connected to the first electrode of the capacitor. The capacitor further includes the second electrode disposed opposite to the first electrode. The data signal line is connected to the first transistor and is configured to: supply the first reference voltage to the first transistor in a standby stage and a precharging stage, supply a data voltage to the first transistor in a data writing stage, and read data in response to whether the first transistor is turned on in a data reading stage. The auxiliary signal line is connected to the first transistor and the second transistor, and is configured to: supply the first reference voltage to the first transistor in the standby stage and the precharging stage, be floated in the data writing stage, and simultaneously supply the second reference voltage to both the first transistor and the second transistor in the data reading stage. A sum of a maximum data voltage corresponding to the data and a threshold voltage of the first transistor is a benchmark voltage, and the first reference voltage is greater than the benchmark voltage.

According to some embodiments, the circuit for reading and writing data further includes the first control signal line and the second control signal line. The first control signal line is connected to the second electrode of the capacitor and is configured to: apply the first write control voltage to the second electrode of the capacitor in the precharging stage and the data writing stage, and apply a read control voltage to the second electrode of the capacitor in the data reading stage. The second control signal line is connected to the second transistor and is configured to: control the second transistor to be turned off in the standby stage and the data reading stage, and control the second transistor to be turned on in the precharging stage and the data writing stage.

According to some embodiments, the data signal line is further configured to: in a data holding stage, supply the first reference voltage to the first transistor. The second control signal line is further configured to: in the data holding stage, control the second transistor to be turned off after the voltage of the data signal line is the first reference voltage. The auxiliary signal line is further configured to: in the data holding stage, simultaneously supply the first reference voltage to both the first transistor and the second transistor after the second transistor is turned off.

Furthermore, the first control signal line is further configured to: in the data holding stage, apply the second write control voltage to the second electrode of the capacitor after the second transistor is turned off. The second write control voltage is less than the first write control voltage.

According to other embodiments, the first control signal line is further configured to: in a data holding stage, apply the second write control voltage to the second electrode of the capacitor. The second write control voltage is less than the first write control voltage. The data signal line is further configured to: in the data holding stage, supply the first reference voltage to the first transistor after a voltage of the second electrode is the second write control voltage. The second control signal line is further configured to: in the data holding stage, control the second transistor to be turned off after the data signal line supplies the first reference voltage. The auxiliary signal line is further configured to: in the data holding stage, simultaneously supply the first reference voltage to both the first transistor and the second transistor after the second transistor is turned off.

According to some embodiments, the first transistor includes the first gate, the first terminal, and the second terminal. The second transistor includes the second gate, the first terminal, and the second terminal. The first gate and the first terminal of the second transistor are both connected to the first electrode of the capacitor. The second electrode of the capacitor is connected to the first control signal line. The second gate is connected to the second control signal line. The first terminal of the first transistor is connected to the data signal line. The second terminal of the first transistor and the second terminal of the second transistor are respectively connected to the auxiliary signal line.

According to some embodiments, multiple memory cells exist. The multiple memory cells are arranged in rows along the first direction and arranged in columns along the second direction. The first direction intersects with the second direction intersect. Memory cells in one row share one first control signal line and one second control signal line. Memory cells in one column share one data signal line and one auxiliary signal line.

According to some embodiments, the circuit for reading and writing data further includes the first reference voltage terminal and the second reference voltage terminal.

The first reference voltage terminal is correspondingly connected to the data signal line through the first gating circuit and is correspondingly connected to the auxiliary signal line through the second gating circuit. The first reference voltage terminal is configured to supply the first reference voltage. The first gating circuit is configured to selectively connect the first reference voltage terminal and the data signal line in the standby stage and the precharging stage. The second gating circuit is configured to selectively connect the first reference voltage terminal and the auxiliary signal line in the standby stage and the precharging stage.

The second reference voltage terminal is correspondingly connected to the auxiliary signal line through the third gating circuit. The second reference voltage terminal is configured to supply the second reference voltage. The third gating circuit is configured to selectively connect the second reference voltage terminal and the auxiliary signal line in the data reading stage.

According to some embodiments, another aspect of the present disclosure further provides a memory. The memory includes at least one memory cell, and at least one first bit line, at least one second bit line, at least one first word line, and at least one second word line that are correspondingly connected to the at least one memory cell. Each of the at least one memory cell includes a capacitor, the first transistor, and the second transistor. The capacitor includes the first electrode and the second electrode that are insulated. Each of the first transistor and the second transistor includes a gate, the first terminal, and the second terminal. The first electrode, the gate of the first transistor, and the first terminal of the second transistor are connected with each other, and an intersection point where the first electrode, the gate of the first transistor and the first terminal of the second transistor are connected with each other is a storage node. The first word line is connected to the second electrode. The second word line is connected to the gate of the second transistor. The first bit line is connected to the first terminal of the first transistor. The second bit line is simultaneously connected to the second terminal of the first transistor and the second terminal of the second transistor. The first bit line is configured to: supply a data voltage of data to be written in a data writing stage, and read data written into the storage node in response to whether the first transistor is turned on in a data reading stage.

According to some embodiments, another aspect of the present disclosure further provides a method for driving a memory. The memory is applied to the memory described above. The method includes the following operations.

In the precharging stage, the first bit line supplies the first reference voltage to the first terminal of the first transistor. The second bit line simultaneously supplies the first reference voltage to both the second terminal of the first transistor and the second terminal of the second transistor. The first word line applies the first write control voltage to the second electrode. The second word line applies the third write control voltage to the gate of the second transistor to control the second transistor to be turned on, so as to precharge the storage node. The first reference voltage is greater than a sum of a maximum data voltage to be written into the at least one memory cell and a threshold voltage of the first transistor.

In the data writing stage, the second bit line is floated, the first bit line supplies the data voltage to the first terminal of the first transistor, and the first transistor is turned on. When the storage node is discharged to a stable state, the data corresponding to the data voltage is written into the storage node.

In the data reading stage, the second word line applies the fourth write control voltage to the gate of the second transistor, and the second transistor is in an off state. The first word line applies a read control voltage to the second electrode. The second bit line simultaneously supplies the second reference voltage to both the second terminal of the first transistor and the second terminal of the second transistor. The first bit line reads the data written into the storage node in response to whether the first transistor is turned on.

According to some embodiments, another aspect of the present disclosure further provides an electronic device. The electronic device includes the circuit for reading and writing data described in the above embodiments or the memory described in the above embodiments.

Details of one or more embodiments of the present disclosure are described in the accompanying drawings and description below. Other features, objectives, and advantages of the present disclosure will become apparent from the description, the accompanying drawings, and the claims.

### BRIEF DESCRIPTION OF THE DRAWINGS

In order to more clearly illustrate the technical solutions of the embodiments of the present disclosure, the accompanying drawings used in the description of the embodiments will be briefly introduced below. It is apparent that the accompanying drawings in the following description are merely some embodiments of the present disclosure. For those of ordinary skill in the art, other drawings may be obtained from these accompanying drawings without inventive effort.

FIG. 1 is a circuit schematic diagram of a memory cell with a 2T1C architecture provided in the related art.

FIG. 2 is a circuit schematic diagram of a circuit for reading and writing data or a memory provided by some embodiments of the present disclosure.

FIG. 3 is a structural block diagram of another circuit for reading and writing data or memory provided by some embodiments of the present disclosure.

FIG. 4 is an equivalent circuit diagram of the circuit for reading and writing data or memory illustrated in FIG. 3.

FIG. 5 is a timing diagram of a method for reading and writing data or a method for driving a memory provided by some embodiments of the present disclosure.

FIG. 6 is another timing diagram of a method for reading and writing data or a method for driving a memory provided by some embodiments of the present disclosure.

FIG. 7 is yet another timing diagram of a method for reading and writing data or a method for driving a memory provided by some embodiments of the present disclosure;

FIG. 8 is a curve chart illustrating changes of current-voltage characteristics of the first transistor when different read control voltages are applied in a data reading stage provided by some embodiments of the present disclosure.

### DETAILED DESCRIPTION

To facilitate understanding of the present disclosure, a more comprehensive description for the present disclosure will be made below with reference to the related accompanying drawings. Embodiments of the present disclosure are given in the accompanying drawings. However, the present disclosure may be implemented in many different forms and is not limited to the embodiments described herein. Instead, these embodiments are provided to make the disclosure content of the present disclosure more thorough and comprehensive.

Unless otherwise defined, all technical and scientific terms used herein have the same meaning as commonly understood by one of ordinary skill in the art to which the present disclosure belongs. The terms used herein in the description of the present disclosure are for the purpose of describing specific embodiments only and are not intended to limit the present disclosure.

The “embodiments” mentioned herein means that specific features, structures, or characteristic described in combination with the embodiments may be included in at least one embodiment of the present disclosure. The appearances of this term in various places in the specification are not necessarily referring to the same embodiment, nor are separate or alternative embodiments that are mutually exclusive with other embodiments. It is to be explicitly and implicitly understood by those skilled in the art that the embodiments described herein may be combined with other embodiments.

It is to be understood that the terms “first”, “second”, “third”, “fourth”, etc. used in the present disclosure may be used herein to describe various elements, but these elements are not limited by these terms. These terms are only used to distinguish one element from another element. For example, without departing from the scope of the present disclosure, the first transistor may be referred to as the second transistor, and similarly, the second transistor may be referred to as the first transistor. Both the first transistor and the second transistor are transistors, but they are not the same one transistor.

It may be understood that the term “connected” in the following embodiments, if there is transmission of the electrical signal or data between the connected circuits, modules, units, etc., should be understood as “electrically connected”, “communicatively connected”, etc.

As used herein, the singular forms “a”, “an”, and “the” are intended to include the plural forms as well, unless the context clearly indicates otherwise. It should be further understood that the terms “including/containing”, or “having”, etc. specify the presence of stated features, integers, steps, operations, components, parts, or combinations thereof, but do not exclude the presence or addition of one or more other features, integers, steps, operations, components, parts, or combinations thereof. Also, the term “and/or” as used in this specification includes any and all combinations of the associated listed items.

Currently, in three-dimensional dynamic random-access memory, each memory cell may adopt architectures such as 1T1C, 2T0C, and 2T1C. However, when the memory cell adopts the 2T1C architecture, more new challenges are easily faced.

For example, as illustrated in FIG. 1, a memory cell adopting the 2T1C architecture includes: a read transistor T_r, a write transistor T_w, and a capacitor C whose first electrode is connected to both the second terminal of the read transistor T_r and the second terminal of the write transistor T_w. The second electrode of the capacitor C is connected to a ground voltage terminal. A gate of the read transistor T_r is connected to a read word line Read-WL, and the first terminal of the read transistor T_r is connected to a read bit line Read-BL. A gate of the write transistor T_w is connected to a write word line Write-WL, and the first terminal of the write transistor T_w is connected to a write bit line Write-BL.

Some embodiments of the present disclosure provide a novel circuit design for the memory cell and a driving method. The memory cell includes 2 transistors (2T) and 1 capacitor (1C). The 2T participate in precharging, and 2T participate in writing data, thereby implementing the compensation for the Vth of the read transistor in the writing stage.

In the embodiments of the present disclosure, the read transistor T_r and write transistor T_w of the memory cell operate relatively independently when implementing data writing and data reading. That is, data is written into the capacitor C depending on the turned-on write transistor T_w, while keeping that the read transistor T_r is in an off state, and data is read from the capacitor C depending on whether the read transistor T_r is turned on, while keeping that the write transistor T_w is in an off state. However, limited by manufacturing processes and the service life of the transistors, the threshold voltages of the transistors (especially the read transistor T_r) are prone to vary significantly, which inevitably has adverse effects on data reading, and leads to an impact on the accuracy of data reading.

In at least some embodiments of the present disclosure, the read transistor participates in both precharging and data writing in the data writing stage, and is used for reading data in the reading stage.

Some embodiments of the present disclosure provide a circuit for reading and writing data and a method for reading and writing data, a memory and a method for driving a memory, and an electronic device. The data signal line (or the first bit line) and the auxiliary signal line (or the second bit line) may be used to supply different electrical signals to the first transistor and the second transistor in the memory cell in different stages of the data read-write period, and in combination with the controlling for the control voltages of the capacitor and the second transistor in the memory cell, the threshold compensation voltage of the first transistor is stored into the storage node when data is written into the storage node in the data writing stage. Thus, it is convenient to subsequently read data which is not affected by the threshold voltage of the first transistor through the data signal line in the data reading stage, thereby ensuring the accuracy of reading the stored data and further enhancing the performance of the electronic device. The data signal line (or the first bit line) can not only supply the data voltage of the data to be written in the data writing stage, but also read the written data in response to whether the first transistor is turned on in the data reading stage.

It is to be understood that a memory typically includes multiple memory cells, and the memory cells may be distributed in a two-dimensional single layer or three-dimensional multiple layers. For convenience of description and understanding, the circuit for reading and writing data and the method for reading and writing data in the following embodiments are introduced by using one memory cell and the corresponding driving as an example. Furthermore, when describing the solutions provided by the embodiments of the present disclosure, the circuit for reading and writing data mentioned herein primarily refers to the circuit within the memory cell array and does not include peripheral circuits (e.g., row address driver circuits, column address driver circuits, etc.). This circuit for reading and writing data includes the components of at least one memory cell and the drive line(s) connected to the at least one memory cell.

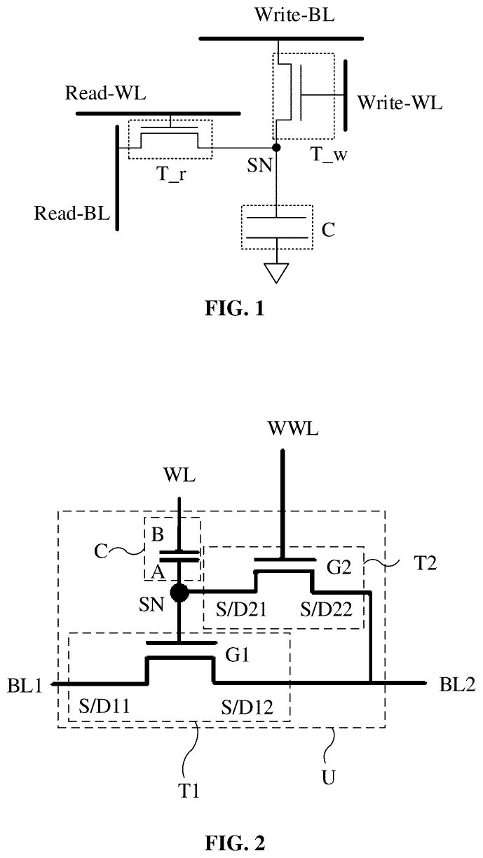

Referring to FIG. 2, the circuit for reading and writing data provided in some embodiments of the present disclosure includes a memory cell U, a data signal line BL1, and an auxiliary signal line BL2.

The memory cell U is configured to store data, and includes the first transistor T1, the second transistor T2, and a capacitor C.

As illustrated in FIG. 2, the capacitor C includes two electrodes that are insulated from each other, one of the two electrodes is the first electrode A, which is connected to both the first gate G1 of the first transistor T1 and the first terminal S/D21 of the second transistor T2. The capacitor C further includes the second electrode B disposed opposite the first electrode A, and the second electrode B is connected to the first control signal line WL. The intersection point where the first electrode A of the capacitor C, the first gate G1 of the first transistor T1, and the first terminal S/D21 of the second transistor T2 are connected with each other is a storage node SN.

The data read-write timing of the memory cell U includes: a data writing stage, a data reading stage, and a standby stage (which may be understood as a stand by stage) before data writing or reading. In the embodiments of the present disclosure, a precharging stage is further included before the data writing stage, and a data holding stage is further included after the data writing stage.

The data signal line BL1 is connected to the first transistor T1, and is configured to supply the first reference voltage to the first transistor T1 in the standby stage and the precharging stage, to supply a data voltage to the first transistor T1 in the data writing stage, and to read data in response to whether the first transistor T1 is turned on in the data reading stage. Here, after the data voltage is supplied to the first transistor T1 in the data writing stage, data of the data voltage may be stored.

The auxiliary signal line BL2 is connected to the first transistor T1 and the second transistor T2, and is configured to supply the first reference voltage to the first transistor T1 in the standby stage and the precharging stage, to be floated in the data writing stage, and to simultaneously supply the second reference voltage to both the first transistor T1 and the second transistor T2 in the data reading stage.

In the embodiments of the present disclosure, a sum of the maximum data voltage corresponding to the data that can be stored in the memory cell U and the threshold voltage of the first transistor T1 is a benchmark voltage, and the first reference voltage provided by the data signal line BL1 and the auxiliary signal line BL2 is greater than the benchmark voltage.

Here, the maximum data voltage corresponding to the data that can be stored in the memory cell U refers to the voltage corresponding to the data voltage with maximum absolute value in the data (i.e., data “1” or data “0”) that can be stored in the memory cell U. For example, the data that can be stored in the memory cell U includes data “0” and data “1”. Both the data voltage Vdata1 corresponding to the data “1” and the data voltage Vdata0 corresponding to the data “0” may be positive voltages or negative voltages. Further, the absolute value of the data voltage Vdata1 corresponding to the data “1” is greater than the absolute value of the data voltage Vdata0 corresponding to the data “0”. Based on this, the data voltage corresponding to the data “1” may be the maximum data voltage of data that may be stored in the memory cell U, and vice versa.

It may be understood that when the data voltage Vdata1 corresponding to the data “1” is the maximum data voltage of data that can be stored in the memory cell U, the sum of the maximum data voltage and the threshold voltage Vth of the first transistor T1 is the benchmark voltage, that is, the benchmark voltage is Vdata1 +Vth. Here, for convenience of description, the benchmark voltage is defined as the sum of the maximum data voltage and the threshold voltage Vth of the first transistor T1, and is only used to illustrate the value range of the first reference voltage when the benchmark voltage is used as a reference standard. For example, the first reference voltage is greater than the benchmark voltage (i.e., greater than Vdata1+Vth). Further, the difference between the first reference voltage and the benchmark voltage may be reasonably set according to the demand.

For example, the second reference voltage is less than the first reference voltage. In an example in which both the first transistor T1 and the second transistor T2 are N-type transistors, the first reference voltage may be supplied by the first reference voltage terminal, for example, the first reference voltage terminal is a power supply voltage terminal that can provide a rated high-level voltage, and the second reference voltage may be supplied by the second reference voltage terminal, for example, the second reference voltage terminal is a common voltage terminal that can provide a rated low-level voltage.

For example, the second reference voltage is greater than a minimum data voltage of data that can be stored in the memory cell U, and is less than a maximum data voltage of data that can be stored in the memory cell U. For example, Vdata1>the second reference voltage>Vdata0.

Here, it may be understood that in the practical application of the circuit for reading and writing data, considering the coupling effect among the capacitor C, the data signal line BL1, and the auxiliary signal line BL2, the second reference voltage V2 may be greater than the sum of the minimum data voltage and the voltage variable (vector) caused by the coupling effect, and less than the sum of the maximum data voltage and the voltage variable (vector) caused by the coupling effect, so as to clearly distinguish the voltage changes or the current changes caused by the data “1” and the data “0” in the data reading stage. Moreover, because different timings and/or different control voltages cause different coupling effects to the circuit for reading and writing data, the aforementioned voltage variable (vector) may be specifically determined according to the actual situation.

In some embodiments, referring to FIG. 2, the circuit for reading and writing data further includes the first control signal line WL and the second control signal line WWL. The capacitor C includes the first electrode A and the second electrode B. The first transistor T1 includes the first gate G1, the first terminal S/D11, and the second terminal S/D12. The second transistor T2 includes the second gate G2, the first terminal S/D21 and the second terminal S/D22. The first gate G1 and the first terminal S/D21 of the second transistor T2 are both connected to the first electrode A, and the intersection point where the first gate G1, the first terminal S/D21 of the second transistor T2 and the first electrode A are connected with each other is the storage node SN. The second electrode B is connected to the first control signal line WL. The second gate G2 is connected to the second control signal line WWL. The first terminal S/D11 of the first transistor T1 is connected to the data signal line BL1. The second terminal S/D12 of the first transistor T1 and the second terminal S/D22 of the second transistor T2 are respectively connected to the auxiliary signal line BL2.

Here, one of the first terminal S/D11 and the second terminal S/D12 of the first transistor T1 may be a source and the other may be a drain according to the transmission direction of the current. One of the first terminal S/D21 and the second terminal S/D22 of the second transistor T2 may be a source and the other may be a drain.

In FIG. 2, the above two transistors are both N-type transistors, and the types of transistors are not limited in practical applications.

In the embodiments of the present disclosure, the memory cell U includes a capacitor C, and the first transistor T1 and the second transistor T2 that are connected to the first electrode A of the capacitor C. By setting the data signal line BL1 connected to the first transistor T1 in the memory cell U and the auxiliary signal line BL2 connected to the first transistor T1 and the second transistor T2 in the memory cell U, the data signal line BL1 and the auxiliary signal line BL2 may be used to supply different electrical signals to the first transistor T1 and the second transistor T2 in different stages of the data read-write period, respectively, and in combination with the controlling for the control voltages of the second electrode B of the capacitor C and the second transistor T2, the threshold compensation voltage for the first transistor T1 is stored into the storage node SN when data is written into the storage node SN in the data writing stage. Thus, it is convenient to read data which is not affected by the threshold voltage Vth of the first transistor T1 through the data signal line BL1 in the subsequent data reading stage, thereby ensuring the accuracy of reading of the stored data and further enhancing the performance of the electronic device. In addition, in the circuit for reading and writing data provided by the embodiments of the present disclosure, it is not necessary to provide a ground in the memory cell U, such that it is also beneficial to further implement high-density integration of the memory cell U.

It should be noted that, in some embodiments, the first control signal line WL is connected to the second electrode B of the capacitor C, and is configured to: apply the first write control voltage to the second electrode B of the capacitor C in the precharging stage and the data writing stage. Here, the first control signal line WL may also be configured to apply the second write control voltage to the second electrode B of the capacitor C according to the demand.

In some embodiments, the second control signal line WWL is connected to the second gate G2 of the second transistor T2, and is configured to: control the second transistor T2 to be turned off in the standby stage and the data reading stage, and control the second transistor T2 to be turned on in the precharging stage and the data writing stage. The control voltage with which the second control signal line WWL controls the second transistor T2 to be turned on is the third write control voltage. Further, the turn-off of the second transistor T2 may be implemented by controlling a turn-off control voltage (for example, the fourth write control voltage) applied by the second control signal line WWL to the second gate G2.

For example, the first transistor T1 and the second transistor T2 are both N-type transistors. Accordingly, both the first write control voltage and the third write control voltage are high-level voltages, and both the second write control voltage and the fourth write control voltage are low-level voltages. Further, the first write control voltage may be less than the third control voltage, and the first write control voltage may be reasonably set according to the demand. The second write control voltage and the fourth write control voltage may be the same. For example, both the second write control voltage and the fourth write control voltage are ground voltages.

In some embodiments, the write period further includes a data holding stage after the data writing stage.

In some examples, the data signal line BL1 is further configured to: supply the first reference voltage to the first transistor T1 in the data holding stage. The second control signal line WWL is further configured to: in the data holding stage, control the second transistor T2 to be turned off after the voltage of the data signal line BL1 is the first reference voltage. The auxiliary signal line BL2 is further configured to: in the data holding stage, simultaneously supply the first reference voltage to both the first transistor T1 and the second transistor T2 after the second transistor T2 is turned off.

Further, the first control signal line WL is further configured to: in the data holding stage, apply the second write control voltage to the second electrode B of the capacitor C after the second transistor T2 is turned off. The second write control voltage is less than the first write control voltage. Further, the difference between the second write control voltage and the first write control voltage may be reasonably set according to the demand.

In the embodiments of the present disclosure, in the data holding stage after the data is written into the storage node SN, the voltage of the data signal line BL1 is pulled up to the first reference voltage V1, and a voltage difference between the first terminal S/D11 of the first transistor T1 and the storage node SN may be used to enable the first transistor T1 to be in the off state. At this case, the second transistor T2 connecting the storage node SN and the auxiliary signal line BL2 is in an on state, and the voltage of the storage node SN may be maintained stable based on the coupling effect among the capacitor C, the data signal line BL1, and the auxiliary signal line BL2. Thereafter, the second transistor T2 is firstly turned off, and then the first reference voltage is simultaneously supplied to both the first transistor T1 and the second transistor T2 through the auxiliary signal line BL2, thereby preventing the second transistor T2 from generating a leakage current, and thus the data is held in the storage node SN.

It may be understood that in the data reading stage, the data signal line BL1 reads the data in response to whether the first transistor T1 is turned on, which may be implemented as reading the data by a change in the current or voltage transmitted by the data signal line BL1. Therefore, in the data holding stage, after the second transistor T2 is turned off, the first control signal line WL may be configured to apply the second write control voltage to the second electrode B of the capacitor C. The second write control voltage is less than the first write control voltage, such that the voltage of the storage node SN may be pulled down. In this way, not only the off state of the first transistor T1 may be further ensured, so as to prevent the first transistor T1 from generating the leakage current, but also it is convenient to subsequently apply a read control voltage to the second electrode B of the capacitor C through the first control signal line WL, so as to implement the read scan control for the data.

In other examples, the first control signal line WL is further configured to supply the second write control voltage to the second electrode B of the capacitor C in the data holding stage, and the second write control voltage is less than the first write control voltage. The data signal line BL1 is further configured to: in the data holding stage, supply the first reference voltage to the first transistor T1 after the voltage of the second electrode B is the second write control voltage. The second control signal line WWL is further configured to: in the data holding stage, control the second transistor T2 to be turned off after the data signal line BL1 supplies the first reference voltage. The auxiliary signal line BL2 is further configured to: in the data holding stage, simultaneously supply the first reference voltage to both the first transistor T1 and the second transistor T2 after the second transistor T2 is turned off.

In the embodiments of the present disclosure, after the data is written into the storage node SN, the second write control voltage is firstly supplied to the second electrode B of the capacitor C. The second write control voltage is less than the first write control voltage, such that the voltage of the storage node SN may be pulled down to control the first transistor T1 to be in the off state. Thereafter, the voltage of the data signal line BL1 is pulled up to the first reference voltage V1. At this case, since the second transistor T2 connecting the storage node SN and the auxiliary signal line BL2 maintains an on state, the voltage of the storage node SN is maintained stable. Finally, the second transistor T2 is turned off, and the first reference voltage is simultaneously supplied to both the first transistor T1 and the second transistor T2 through the auxiliary signal line BL2, thereby preventing the second transistor T2 from generating a leakage current, and stabilizing the data at the storage node SN.

It should be noted that the above-described controlling for the voltage on the second electrode B of the capacitor C by the first control signal line WL and controlling for the voltage on the second gate G2 of the second transistor T2 by the second control signal line WWL may be described in detail in the method for reading and writing data described later. Here, only the connection relationship and basic functions of the first control signal line WL and the second control signal line WWL will be described.

In some embodiments, the write control voltages supplied by the first control signal line WL and the second control signal line WWL are pulse voltages.

In some embodiments, the first write control voltage supplied by the first control signal line WL in the write period and the read control voltage supplied by the first control signal line WL in the read period may be the same or different.

For example, the first write control voltage and the read control voltage are the same. In an example where both the first transistor T1 and the second transistor T2 are N-type transistors, both the first write control voltage and the read control voltage may be high-level voltages. In an example where both the first transistor T1 and the second transistor T2 are P-type transistors, both the first write control voltage and the read control voltage may be low-level voltages.

For example, the first write control voltage is less than the read control voltage. For example, the voltage absolute value of the first write control voltage is less than the voltage absolute value of the read control voltage.

The above is the memory cell and the method for driving the memory cell provided by the embodiments of the present disclosure. A memory array of the memory cells will be described below.

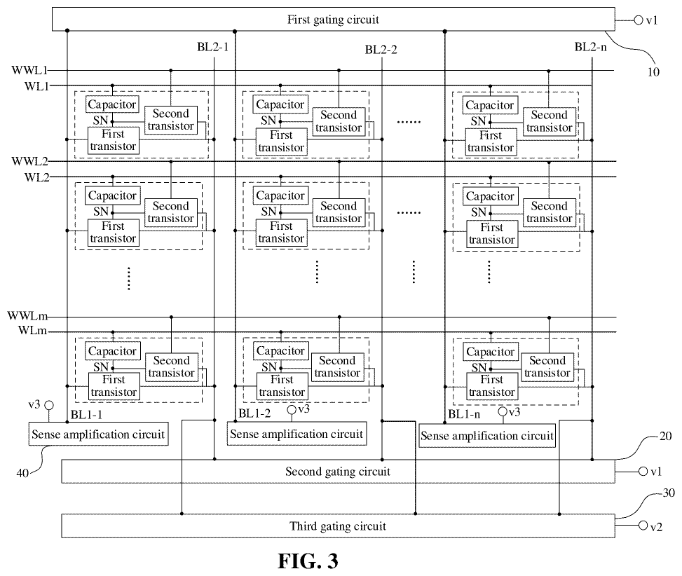

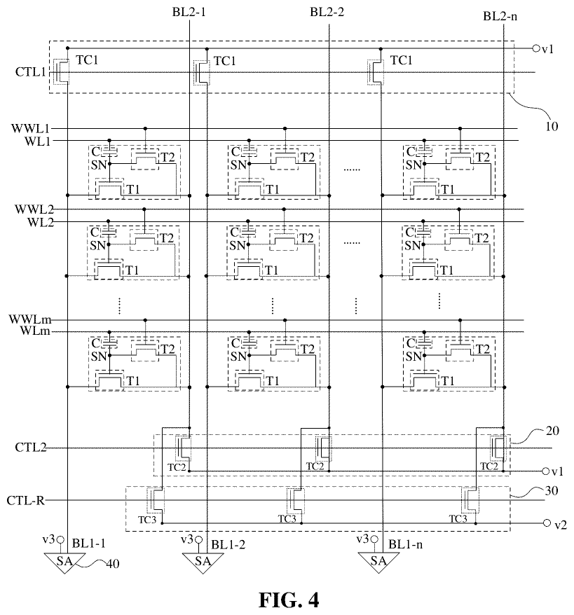

In some embodiments, referring to FIG. 3 and FIG. 4, multiple memory cells U exist. The multiple memory cells U are arranged in rows along the first direction and arranged in columns along the second direction. In the figures, m×n memory cells are schematically illustrated. The first direction intersects with the second direction. Here, the first direction is a row direction, and is also an extending direction of the first control signal line WL and/or the second control signal line WWL. The second direction is a column direction, and is also an extending direction of the data signal line BL1 and/or the auxiliary signal line BL2. The first direction and the second direction are, for example, orthogonal.

For example, as illustrated in FIG. 3 and FIG. 4, the memory cells U in one row share one first control signal line WL and one second control signal line WWL, and the memory cells U in one column share one data signal line BL1 and one auxiliary signal line BL2. The transistors in each memory cell in the figures are N-type transistors as examples.

For example, the coupling capacitance between the data signal line BL1 and the storage node SN is less than the first target threshold. The coupling capacitance between the auxiliary signal line BL2 and the storage node SN is less than the second target threshold. Here, the first target threshold and the second target threshold may be the same or different.

Further, both the first target threshold and the second target threshold may use a less value.

For example, the coupling capacitance between the data signal line BL1 and the storage node SN is the first coupling capacitance. The total coupling capacitance among the data signal line BL1, the capacitor C, and the auxiliary signal line BL2 is the second coupling capacitance. The ratio of the first coupling capacitance and the second coupling capacitance is less than a target value. Further, the less the target value, the better.

In some embodiments, with continued reference to FIG. 3 and FIG. 4, the circuit for reading and writing data further includes the first reference voltage terminal v1 and the second reference voltage terminal v2.

The first reference voltage terminal v1 is connected with the data signal lines BL1 through the first gating circuit 10, and is connected with the auxiliary signal lines BL2 through the second gating circuit 20. The first reference voltage terminal v1 is configured to supply the first reference voltage. The first gating circuit 10 is configured to selectively connect the first reference voltage terminal v1 with the data signal lines BL1 in the standby stage and the precharging stage. The second gating circuit 20 is configured to selectively connect the first reference voltage terminal v1 with the auxiliary signal lines BL2 in the standby stage and the precharging stage.

The second reference voltage terminal v2 is connected to the auxiliary signal lines BL2 through the third gating circuit 30. The second reference voltage terminal v2 is configured to supply the second reference voltage. The third gating circuit 30 is configured to selectively connect the second reference voltage terminal v2 with the auxiliary signal lines BL2 in the data reading stage.

For example, the first reference voltage terminal v1 connected to the data signal lines BL1 and the first reference voltage terminal v1 connected with the auxiliary signal lines BL2 may be the same voltage terminal, or may be different voltage terminals supplying the same voltage.

Further, the first reference voltage terminal v1 connected to the data signal lines BL1 and the first reference voltage terminal v1 connected to the auxiliary signal lines BL2 are different voltage terminals supplying the same voltage, and the different voltage terminals may be provided in different regions, such as being arranged on opposite sides of the array of the memory cells U, respectively.

In some embodiments, as illustrated in FIG. 4, the first gating circuit 10 includes the first selection transistors TC1 connected with the data signal lines BL1 in one-to-one correspondence. The gates of the first selection transistors TC1 are connected to the first gating signal line CTL1. The first terminal of each first selection transistor TC1 is connected to the corresponding data signal line BL1. The second terminals of the first selection transistors TC1 are connected to the first reference voltage terminal v1.

The second gating circuit 20 includes the second selection transistors TC2 connected with the auxiliary signal lines BL2 in one-to-one correspondence. The gates of the second selection transistors TC2 are connected to the second gating signal line CTL2. The first terminal of each second selection transistor TC2 is connected with a corresponding auxiliary signal line BL2. The second terminals of the second selection transistors TC2 are connected to the first reference voltage terminal v1.

The third gating circuit 30 includes the third selection transistors TC3 connected to the auxiliary signal lines BL2 in one-to-one correspondence. The gates of the third selection transistors TC3 are connected to the read gating signal line CTL-R. The first terminal of each third selection transistor TC3 is connected with a corresponding auxiliary signal line BL2. The second terminals of the third selection transistors TC3 are connected to the second reference voltage terminal v2.

For the first terminal and the second terminal of each selection transistor mentioned in the above some embodiments, one of the first terminal and the second terminal may be a source and the other one may be a drain. Furthermore, each selection transistor may be selectively turned on in response to the gating signal provided by the corresponding gating signal line to implement the read-write control for the memory cells U.

In some embodiments, with continued reference to FIG. 3 and FIG. 4, the circuit for reading and writing data may further include one or more sense amplification circuits 40. For example, the circuit for reading and writing data includes multiple sense amplification circuits 40 corresponding to the data signal lines BL1 one-to-one. Further, the end of each data signal line BL1 far away from the first reference voltage terminal v1 is connected to the corresponding sense amplification circuit 40 to read data.

Here, the sense amplification circuit 40 may use a current sense amplification circuit or a voltage sense amplification circuit according to the manner for the circuit for reading and writing data.

For example, the sense amplification circuit 40 is a current sense amplification circuit. Thus, in the data reading stage, the data signal line BL1 continuously supplies the first reference voltage, and the sense amplification circuit 40 may read data by sensing a change in the current transmitted by the data signal line BL1 in response to whether the first transistor T1 is turned on.

For example, the sense amplification circuit 40 is a voltage sense amplification circuit. In the data reading stage, the first reference voltage pre-supplied by the data signal line BL1 may or may not be changed in response to whether the first transistor T1 is turned on, so that the sense amplification circuit 40 may read data by sensing a change in the voltage transmitted by the data signal line BL1.

Further, the circuit structure of the sense amplification circuit 40 is not limited in the embodiments of the present disclosure. For example, the sense amplification circuit 40 is a voltage sense amplification circuit, such as a comparison amplification circuit, and the sense amplification circuit 40 may be connected to the third reference voltage terminal v3 to read data by comparing the difference between the third reference voltage supplied by the third reference voltage terminal v3 and the voltage transmitted by the data signal line BL.

It should be noted that, in above some embodiments, it is to be understood with reference to FIG. 3 and FIG. 4 that both the first write control voltage supplied by the first control signal line WL and the third write control voltage supplied by the second control signal line WWL are control voltages supplied when data writing is performed by the memory cell U. Based on this, it may be understood that for the array of the memory cells U, in addition to supplying the above first write control voltage and the third write control voltage to the row containing the memory cell U that is performing data writing, the first control signal lines WL corresponding to the memory cells U in other rows supplies the second write control voltage, and the second control signal lines WWL corresponding to the memory cells U in other rows supplies the fourth write control voltage, so as to implement row scanning writing of the array of the memory cells U.

Some embodiments of the present disclosure further provide a method for reading and writing data to implement the data read-write process of the above circuit for reading and writing data. The method for reading and writing data may be applied to any memory cell U, and the memory cell U is configured to store data, and for the structure of the memory cell U, the reference is made to the relevant description in the above some embodiments. The method for reading and writing data has the same technical advantages same with the above circuit for reading and writing data.

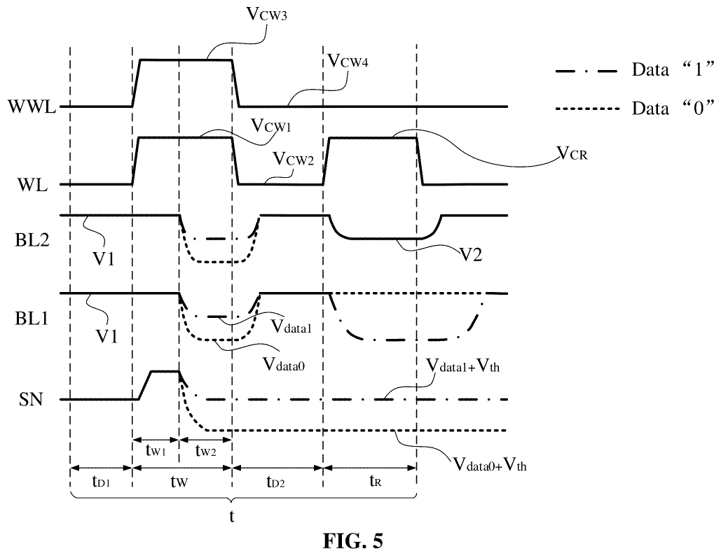

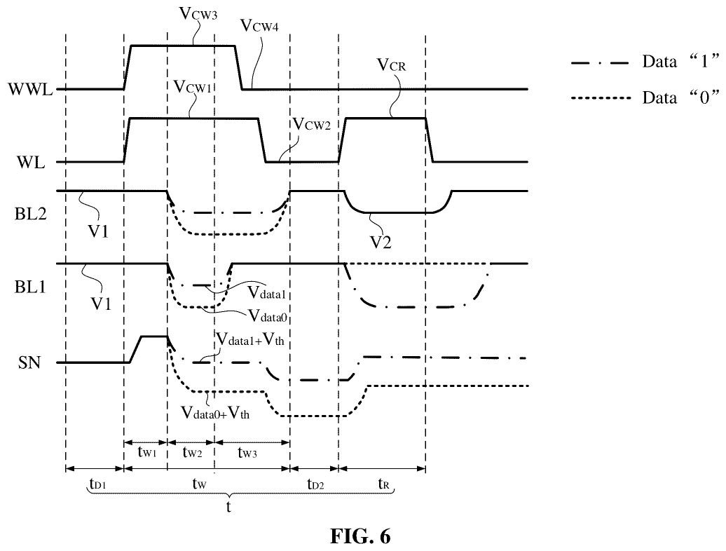

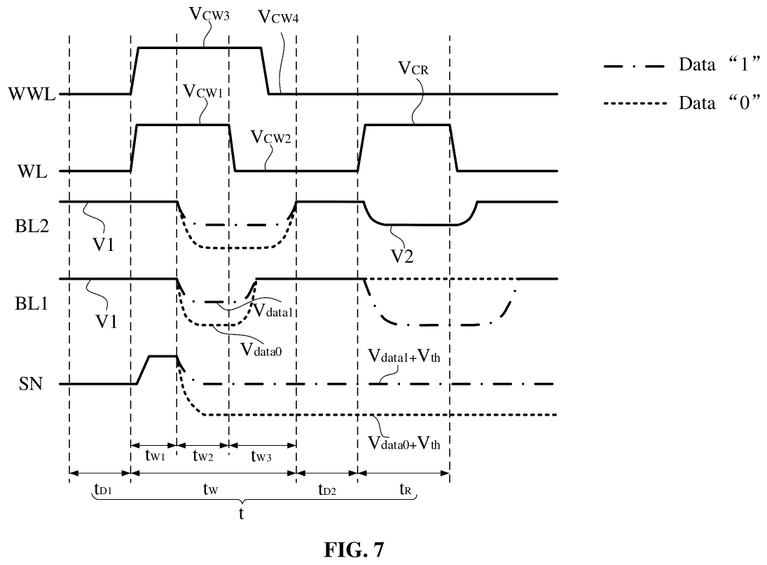

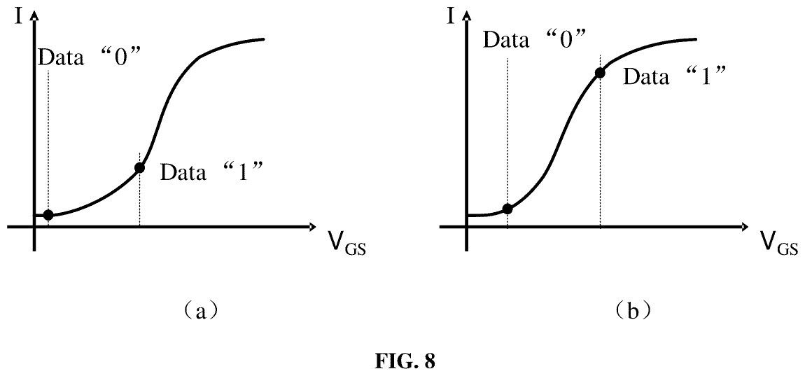

It is to be understood with reference to FIG. 2, FIG. 5, FIG. 6, and FIG. 7 that in the method for reading and writing data provided by some embodiments of the present disclosure, the data read-write period t of the memory cell U includes a writing period tW, a reading period tR, and a standby stage (for example, the first standby stage tD1 and the second standby stage tD2).

In some embodiments, as illustrated in FIG. 5, the writing period tW includes a precharging stage tW1 and a data writing stage tW2. The method for reading and writing data includes the operations S100 and S200.

In operation S100, in the precharging stage tW1, the data signal line BL1 supplies the first reference voltage V1 to the first transistor T1, and the auxiliary signal line BL2 supplies simultaneously the first reference voltage V1 to both the first transistor T1 and the second transistor T2. The first write control voltage VCW1 is applied to the second electrode B of the capacitor C, and the second transistor T2 is turned on to prcharge the storage node SN. A sum of the maximum data voltage corresponding to the data and a threshold voltage Vth of the first transistor Tl is a benchmark voltage, and the first reference voltage V1 is greater than the benchmark voltage.

Here, after the precharging for the storage node SN is completed, the voltage of the storage node SN is the first reference voltage V1.

For example, the data that can be stored in the memory cell U includes data “0” and data “1”. The data voltage Vdata1 corresponding to the data “1” is greater than the data voltage Vdata0 corresponding to the data “0”. Based on this, the data voltage Vdata1 corresponding to the data “1” may be the maximum data voltage of data that can be stored in the memory cell U, and vice versa.

Therefore, when the data voltage Vdata1 corresponding to the data “1” is the maximum data voltage of data that can be stored in the memory cell U, the benchmark voltage is Vdata1+Vth, and the first reference voltage is greater than Vdata1+Vth. Further, the difference between the first reference voltage and the benchmark voltage may be reasonably set according to the demand.

Here, for convenience of description, the benchmark voltage is defined as the sum of the maximum data voltage and the threshold voltage Vth of the first transistor T1, and the definition is only used to illustrate the value range of the first reference voltage when the benchmark voltage is used as a reference standard.

For example, the first transistor T1 and the second transistor T2 are N-type transistors or P-type transistors, both of which are also allowed. For convenience of description, in some embodiments below, both the first transistor T1 and the second transistor T2 are N-type transistors as examples.

In some embodiments, with continued reference to FIG. 2, FIG. 5, FIG. 6, and FIG. 7, in the precharging stage tW1, the first control signal line WL applies the first write control voltage VCW1 to the capacitor C. The second control signal line WWL supplies the third write control voltage VCW3 to the second gate G2 of the second transistor T2. At this case, the data signal line BL1 supplies the first reference voltage V1 to the first terminal S/D11 of the first transistor T1, the auxiliary signal line BL2 supplies the first reference voltage V1 to the second terminal S/D12 of the first transistor T1, and the first transistor T1 is in an off state. For example, both the first write control voltage VCW1 and the third write control voltage VCW3 are high-level voltages.

For example, the first write control voltage VCW1 is less than the third write control voltage VCW3, and the first write control voltage VCW1 may be reasonably set according to the demand.

In operation S200, in the data writing stage tW2, in response to a write command, the auxiliary signal line BL2 is floated, the data signal line BL1 supplies a data voltage Vdata to the first transistor T1, and the first transistor T1 is turned on. When the storage node SN is discharged to a stable state, data corresponding to the data voltage Vdata is written into the storage node SN.

Here, the case that the storage node SN is discharged to the stable state means that the voltage change of the storage node SN tends to zero. After the storage node SN is discharged to the stable state, the voltage of the storage node SN is Vdata+Vth (including approximately equal to Vdata+Vth).

Further, as illustrated in FIG. 5, FIG. 6, and FIG. 7, in the data writing stage tW2, the first control signal line WL continuously applies the first write control voltage VCW1 to the second electrode B of the capacitor C. The second control signal line WWL continuously supplies the third write control voltage VCW3 to the second gate G2 of the second transistor T2. At this case, the data signal line BL1 supplies the data voltage Vdata to the first terminal S/D11 of the first transistor T1, and the auxiliary signal line BL2 is floated.

Further, the data voltage Vdata supplied by the data signal line BL1 is related to data to be written. For example, when the data to be written is data “1”, the data voltage supplied by the data signal line BL1 in the data writing stage tW2 is Vdata1. Alternatively, for example, when the data to be written is data “0”, the data voltage supplied by the data signal line BL1 in the data writing stage tW2 is Vdata0.

In some embodiments, as illustrated in FIG. 3 and FIG. 4, the auxiliary signal line BL2 is connected to the first reference voltage terminal v1 through the second gating circuit 20, and is connected to the second reference voltage terminal v2 through the third gating circuit 30. The case that auxiliary signal line BL2 is floated means that the second gating circuit 20 and the third gating circuit 30 connected with the auxiliary signal line BL2 are both in the off state, and there is no signal input to the end of the auxiliary signal line BL2 that is connected with the second gating circuit 20 and the third gating circuit 30.

In some embodiments, the writing period tW further includes a data holding stage tW3 after the data writing stage tW2.

In some examples, referring to FIG. 6, the method for reading and writing data further includes operation S300.

In operation S300, in the data holding stage tW3, a voltage of the data signal line BL1 is pulled up to the first reference voltage V1, and after the voltage of the data signal line BL1 is the first reference voltage, the second transistor T2 is firstly turned off, and then a voltage of the auxiliary signal line BL2 is pulled up to the first reference voltage V1.

Further, continuing to refer to FIG. 6, after the second transistor T2 is turned off, the method for reading and writing data further includes the following operation. The second write control voltage VCW2 is applied to the second electrode B of the capacitor C. The second write control voltage VCW2 is less than the first write control voltage VCW1. Further, the difference between the second write control voltage and the first write control voltage may be reasonably set according to the demand.

In the embodiments of the present disclosure, in the data holding stage tW3 after the data is written into the storage node SN, the voltage of the data signal line BL1 may be pulled up to the first reference voltage V1, and the voltage difference between the first terminal S/D11 of the first transistor T1 and the storage node SN may be used to enable the first transistor T1 to be in the off state. At this case, the second transistor T2 connecting the storage node SN and the auxiliary signal line BL2 is in the on state, and the voltage of the storage node SN may be maintained stable (for example, maintained at Vdata+Vth) based on the coupling effect among the capacitor C, the data signal line BL1, and the auxiliary signal line BL2. Thereafter, the second transistor T2 is firstly turned off, and then the first reference voltage V1 is supplied simultaneously to both the first transistor T1 and the second transistor T2 through the auxiliary signal line BL2, so that the data may be stored into the storage node SN (the voltage of the storage node SN includes Vdata+Vth).

It may be understood that in the data reading stage tR, the data signal line BL1 reads the data in response to whether the first transistor T1 is turned on, which may be implemented as reading the data by a change in the current or voltage transmitted by the data signal line BL1. Therefore, in the data holding stage tW3, after the second transistor T2 is turned off, the first control signal line WL may be configured to apply the second write control voltage VCW2 to the second electrode B of the capacitor C. The second write control voltage VCW2 is less than the first write control voltage VCW1, such that the voltage of the storage node SN may be pulled down. In this way, not only the off state of the first transistor T1 may be further ensured, so as to prevent the first transistor T1 from generating the leakage current, but also it is convenient to subsequently apply a read control voltage VCR to the second electrode B of the capacitor C through the first control signal line WL, so as to implement the read scan control for the data.

Here, referring to FIG. 6, in the data holding stage tW3, after the second transistor T2 is turned off, the voltage of the auxiliary signal line BL2 may be firstly pulled up to the first reference voltage V1, or the second write control voltage VCW2 is firstly applied to the second electrode B of the capacitor C through the first control signal line WL, or these two operations are performed simultaneously.

Furthermore, when the second write control voltage VCW 2 is applied to the second electrode B of the capacitor C through the first control signal line WL after the second transistor T2 is turned off, the voltage of the storage node SN changes accordingly. For example, when the second write control voltage VCW2 is a low-level voltage, if the data written into the storage node SN is data “1”, the voltage of the storage node SN may be accordingly changed to: Vdata1+Vth −ΔV, and if the data written into the storage node SN is data “0”, the voltage of the storage node SN may be accordingly changed to: Vdata0+Vth−ΔV.

Accordingly, in the subsequent data reading stage tR, when the first control signal line WL applies the read control voltage VCR to the second electrode B of the capacitor C, the voltage of the storage node SN is changed accordingly. For example, when the read control voltage VCR is a high-level voltage, if the data written into the storage node SN is data “1”, the voltage of the storage node SN may be changed to: Vdata1+Vth−ΔV+ΔV′, and if the data written into the storage node SN is data “0”, the voltage of the storage node SN may be changed to: Vdata0+Vth−ΔV+ΔV′.

In the embodiments of the present disclosure, although the voltage of the storage node SN changes after the first control signal line WL applies the second write control voltage VCW2 or the read control voltage VCR to the second electrode B of the capacitor C, the voltage of the storage node SN always includes the data voltage Vdata corresponding to the written data and the threshold voltage Vth of the first transistor T1, and the changes for the voltage of the storage node SN is the same for different data voltages (for example, Vdata1 and Vdata0), thus the accuracy for reading data is not affected in the data reading stage tR.

In some other examples, referring to FIG. 7, the method for reading and writing data further includes operation S300′.

In the operation S300′, in the data holding stage tW3, the second write control voltage VCW2 is firstly applied to the second electrode B of the capacitor C, and the voltage of the data signal line BL1 is pulled up to the first reference voltage V1. Then the second transistor T2 is turned off, and the voltage of the auxiliary signal line BL2 is pulled up to the first reference voltage V1. The second write control voltage VCW2 is less than the first write control voltage VCW1.

Here, it may be understood that the turn-off of the second transistor T2 may be implemented by controlling a turn-off control voltage (that is, the fourth write control voltage VCW4) applied by the second control signal line WWL to the second gate G2.

For example, the second write control voltage VCW2 and the fourth write control voltage VCW4 are the same.

For example, the first transistor T1 and the second transistor T2 are both N-type transistors. Accordingly, the second write control voltage VCW2 and the fourth write control voltage VCW4 are both low-level voltages.

In the embodiments of the present disclosure, after the data is written into the storage node SN, the second write control voltage VCW2 is firstly applied to the second electrode B of the capacitor C. The second write control voltage VCW2 is less than the first write control voltage VCW1, such that the voltage of the storage node SN may be pulled down to control the first transistor T1 to be in the off state. Thereafter, the voltage of the data signal line BL1 is pulled up to the first reference voltage V1. At this case, since the second transistor T2 connecting the storage node SN and the auxiliary signal line BL2 remains in the on state, the voltage of the storage node SN is maintained stable (for example, maintained at Vdata+Vth). Finally, the second transistor T2 is turned off, and then the first reference voltage V1 is simultaneously supplied to both the first transistor T1 and the second transistor T2 through the auxiliary signal line BL2, thereby preventing the second transistor T2 from generating a leakage current and stabilizing the data at the storage node SN (for example, the voltage of the storage node SN is Vdata+Vth).

In some embodiments, as illustrated in FIG. 5, FIG. 6, and FIG. 7, the reading period tR includes a data reading stage tR. The method for reading and writing data further includes operation S400.

In the operation S400, in the data reading stage tR, in response to a read command, the read control voltage VCR is applied to the second electrode B of the capacitor C, and the second reference voltage V2 is simultaneously supplied to both the first transistor T1 and the second transistor T2 by the auxiliary signal line BL2. Here, the data signal line BL1 is further configured to read data in response to whether the first transistor T1 is turned on.

For example, the second reference voltage V2 is less than the first reference voltage V1.

For example, the second reference voltage V2 is greater than the minimum data voltage of data that can be stored in the memory cell U, and is less than the maximum data voltage of data that can be stored in the memory cell U. For example, Vdata1>V2>Vdata0.

Here, it may be understood that in the practical application of the circuit for reading and writing data, considering the coupling effect among the capacitor C, the data signal line BL1, and the auxiliary signal line BL2, the second reference voltage V2 may be greater than the sum of the minimum data voltage and the voltage variable (vector) caused by the coupling effect, and less than the sum of the maximum data voltage and the voltage variable (vector) caused by the coupling effect.

In some embodiments, the first write control voltage VCW1 supplied by the first control signal line WL in the writing period tW and the read control voltage VCR supplied by the first control signal line WL in the reading period tR may be the same or different.

For example, the first write control voltage VCW1 and the read control voltage VCR are the same.

For example, the first write control voltage VCW1 is less than the read control voltage VCR.

Here, the case that the read control voltage VCR is applied to the second electrode B of the capacitor C in response to the read command indicates that it may ensure that the first transistor T1 is in different states when different data are stored in the storage node SN by applying an appropriate voltage by the first control signal line WL.

The figure (a) and figure (b) of FIG. 8 respectively illustrate current-voltage characteristic curve graphs of the first transistor T1 when two different read control voltages VCR are applied to the second electrode B of the capacitor C. The read control voltage VCR corresponding to the figure (a) is less than the read control voltage VCR corresponding to the figure (b). By comparing figures (a) and (b) in FIG. 8, it may be seen that reasonably selecting the magnitude of the read control voltage VCR may ensure that the first transistor T1 can have an obvious on or off state when the storage node SN stores data “0” or data “1”, so as to facilitate reading data.

In some embodiments, it is to be understood in combination with FIG. 5, FIG. 6, FIG. 7, and FIG. 8 that the data written into the storage node SN includes “1” or a “0”. In the data reading stage tR, after the read control voltage VCR is applied to the second electrode B of the capacitor C:
when the data stored into the storage node SN is “1”, the gate-source voltage VGS of the first transistor T1 (i.e., the voltage difference between the first gate G1 and the second terminal S/D12) is great, and is greater than the threshold voltage Vth of the first transistor T1, and the first transistor T1 is in an on state; and
when the data stored into the storage node SN is “0”, the gate-source voltage VGS of the first transistor T1 (i.e., the voltage difference between the first gate G1 and the second terminal S/D12) is less, and is less than the threshold voltage Vth of the first transistor T1, and the first transistor T1 is in an off state.

In order to more clearly explain the data reading process in the data reading stage tR, the data reading method illustrated in FIG. 5 and FIG. 7 is exemplified below, and the data reading method illustrated in FIG. 6 may be adaptively understood.

In the data reading stage tR, if the voltage of the first gate G1 of the first transistor T1 is the voltage after data “1” is written into the storage node SN, it is equal to Vdata1+Vth. The voltage of the second terminal S/D12 of the first transistor T1 is the second reference voltage V2 supplied by the auxiliary signal line BL2. The gate-source voltage of the first transistor T1 is: VGS=Vdata1+Vth−V2. Since V2 is less than Vdata1, the gate-source voltage VGS of the first transistor T1 is greater than Vth.

In the data reading stage tR, if the voltage of the first gate G1 of the first transistor T1 is the voltage after data “0” is written into the storage node SN, it is equal to Vdata0+Vth. The voltage of the second terminal S/D12 of the first transistor T1 is the second reference voltage V2 supplied by the auxiliary signal line BL2. The gate-source voltage of the first transistor T1 is that: VGS=Vdata0+Vth−V2. Since V2 is greater than Vdata0, the gate-source voltage VGS of the first transistor T1 is less than Vth.

Further, it is to be understood with reference to FIG. 3, FIG. 4, FIG. 5, FIG. 6, and FIG. 7 that according to the manner for the circuit for reading and writing data reading data, the manner for reading data by the data signal line BL1 in response to whether the first transistor T1 is turned on may be implemented as a current sense read or a voltage sense read.

For example, in the data reading stage tR, the data signal line BL1 continuously supplies the first reference voltage V1, and the sense amplification circuit 40 to which the data signal line BL1 is connected may read data by sensing a change in the current transmitted by the data signal line BL1 in response to whether the first transistor T1 is turned on.

For example, in the data reading stage tR, the first reference voltage V1 pre-supplied by the data signal line BL1 may or may not be changed in response to whether the first transistor T1 is turned on, so that the sense amplification circuit 40 may read data by sensing a change in the voltage transmitted by the data signal line BL1.

It is to be understood that, in some embodiments, referring to FIG. 5, FIG. 6, and FIG. 7, the data read-write period t further includes a standby stage (i.e., stand by stage) before the precharging stage tW1 and/or before the data reading stage tR.

For example, as illustrated in FIG. 6 and FIG. 7, the data read-write period t further includes a data holding stage tW3 after the data writing stage tW2. The data reading stage tR is after the data holding stage tW3. The standby stage includes the first standby stage tD1 before the precharging stage tW1, and the second standby stage tD2 that is after the data holding stage tW3 and before the data reading stage tR.

Accordingly, the method for reading and writing data provided by the embodiments of the present disclosure further includes the following operation.

In the standby stage (including the first standby stage tD1 and the second standby stage tD2), the first transistor T1 and the second transistor T2 are in an off state, the data signal line BL1 supplies the first reference voltage V1 to the first transistor T1, and the auxiliary signal line BL2 simultaneously supplies the first reference voltage V1 to both the first transistor T1 and the second transistor T2.

In the embodiments of the present disclosure, in the standby stage, the first reference voltage V1 may be supplied to the first terminal of the first transistor T1 by using the data signal line BL1, and the first reference voltage V1 may be supplied to the second terminal of the first transistor T2 by using the auxiliary signal line BL2, thereby ensuring that there is no large voltage difference between the first terminal and the second terminal of the first transistor T1, and effectively reducing the risk of generation of leakage current, especially in a case that the first reference voltage V1 is a high-level voltage.

In addition, it may be understood that the first standby stage tD1 and the second standby stage tD2 mentioned in the above some embodiments are the standby stage mentioned in the above circuit for reading and writing data. In combination with the foregoing description, the first standby stage tD1 may be independent from the writing period tw, and the second standby stage tD2 may be independent from the reading period tR. Further, based on the fact that the voltage signals supplied by the data signal line BL1, the auxiliary signal line BL2, the first control signal line WL, and the second control signal line WWL in the first standby stage tD1 and the second standby stage tD2 are the same, the first standby stage tD1 and the second standby stage tD2 may be regarded as the same standby stage, so that different read-write periods are entered in response to different received commands. For example, a writing period is entered when a write command is received, or a reading period is entered when a read command is received.

It may be understood that in the first standby stage tD1 and the second standby stage tD2, the first control signal line WL applies the second write control voltage VCW2 to the second electrode B of the capacitor C, and the second control signal line WWL applies the fourth write control voltage VCW4 to the second gate G2 of the second transistor T2.

For example, the second write control voltage VCW2 is same as the fourth write control voltage VCW4.

For example, the first transistor T1 and the second transistor T2 are both N-type transistors. The second write control voltage VCW2 and the fourth write control voltage VCW4 are both low-level voltages.

In the embodiments of the present disclosure, the memory cell U is configured to store data, and includes a capacitor C, and the first transistor T1 and the second transistor T2 that are connected to the first electrode A of the capacitor C. In the embodiments of the present disclosure, by setting the data signal line BL2 connected to the first transistor T1 in the memory cell U, and setting the auxiliary signal line BL2 connected to the first transistor T1 and the second transistor T2 in the memory cell U, the storage node SN may be precharged in the precharging stage tW1 after the data signal line BL1 supplies the first reference voltage V1 to the first transistor T1, the auxiliary signal line BL2 simultaneously supplies the first reference voltage V1 to both the first transistor T1 and the second transistor T2, the first control signal line WL supplies the first write control voltage VCW1 to the second electrode B of the capacitor C, and the second transistor T2 is turned on. Based on the fact that the first reference voltage V1 is greater than the benchmark voltage (i.e., the sum of the maximum data voltage corresponding to data that can be stored in the memory cell U and the threshold voltage of the first transistor T1, for example, Vdata1+Vth), i.e., V1>(Vdata1+Vth), the voltage of the storage node SN (= or ≈V1) may be greater than the benchmark voltage, for example, greater than (Vdata1+Vth), after precharging the storage node SN. Thus, in the data writing stage tW2, in response to the write command, after the auxiliary signal line BL2 is floated and the data signal line BL1 supplies the data voltage Vdata to the first transistor T1, the first transistor T1 is turned on, and the storage node SN may be naturally discharged to a stable state to write the data corresponding to the above data voltage Vdata.

In the embodiments of the present disclosure, since the voltage of the storage node SN after precharging is greater than the benchmark voltage, for example, greater than (Vdata1+Vth), that is, the voltage of the storage node SN is not only greater than the data voltage Vdata supplied by the data signal line BL1, but also the difference between the voltage of the storage node SN and the above data voltage Vdata is greater than the threshold voltage Vth of the first transistor T1, after the storage node SN is discharged to a stable state, the voltage of the storage node SN is the sum of the above data voltage Vdata and the threshold voltage Vth of the first transistor T1 (that is, the voltage of the storage node SN = or ≈Vdata+Vth), so that the threshold compensation voltage (= or ≈Vth) of the first transistor T1 may be stored in the storage node SN while writing data.

On the basis of above, after the data is written, in the some embodiments of the present disclosure, the first transistor T1 and the second transistor T2 may be turned off (with the reference to the description related to the data holding stage tW3 for detail). Further, in the second standby stage tD2, the data signal line BL1 and the auxiliary signal line BL2 may be configured to supply the first reference voltage V1 to the first transistor T1, respectively, and the auxiliary signal line BL2 may be configured to supply the first reference voltage V1 to the second transistor T2. At this case, both the first transistor T1 and the second transistor T2 are in the off state, thus the voltage of the storage node SN can be maintained stable.

Thereafter, in the data reading stage tR, in response to the read command, the read control voltage VCR may be supplied to the second electrode B of the capacitor C, and the second reference voltage V2 may be simultaneously supplied to both the first transistor T1 and the second transistor T2 through the auxiliary signal line BL2. After the data signal line BL1 supplies the first reference voltage V1, the auxiliary signal line BL2 supplies the second reference voltage V2, and the read control voltage VCR is supplied to the second electrode B of the capacitor C, the magnitude of the voltage of the storage node SN may affect the case whether the first terminal S/D11 and the second terminal S/D12 of the first transistor T1 is conductive, so that the data signal line BL1 reads data in response to whether the first transistor T1 is turned on. Since the voltage of the storage node SN includes the threshold compensation voltage (= or ≈Vth) of the first transistor T1, data read by the data signal line BL1 in response to whether the first transistor T1 is turned on may not be affected by the threshold voltage Vth of the first transistor T1, thereby ensuring the accuracy of reading the stored data, thereby further improving memory performance.

Yet another aspect of some embodiments of the present disclosure further provides a memory. It is to be understood in combination with FIG. 2, FIG. 3, and FIG. 4, the memory includes at least one memory cell U, and the first bit line(s) BL1, the second bit line(s) BL2, the first word line(s) WL, and the second word line(s) WWL that are correspondingly connected with the at least one memory cell U. The memory cell U includes a capacitor C, the first transistor T1, and the second transistor T2. The capacitor C includes the first electrode A and the second electrode B that are insulated. Each of the first transistor T1 and the second transistor T2 includes a gate, the first terminal and the second terminal. The first electrode A, the gate G1 of the first transistor T1, and the first terminal S/D21 of the second transistor T2 are connected with each other, and an intersection point where the first electrode A, the gate G1 of the first transistor T1, and the first terminal S/D21 of the second transistor T2 are connected with each other is the storage node SN. The first word line WL is connected to the second electrode B, and the second word line WWL is connected to the gate G2 of the second transistor T2. The first bit line BL1 is connected to the first terminal S/D11 of the first transistor T1, and the second bit line BL2 is connected to both the second terminal S/D12 of the first transistor T1 and the second terminal S/D22 of the second transistor T2. The first bit line BL1 is configured to: supply a data voltage of data to be written in a data writing stage, and read data written into the storage node in response to whether the first transistor T1 is turned on in a data reading stage.

Here, according to the transmission direction of the current, one of the first terminal S/D11 and the second terminal S/D12 of the first transistor T1 may be a source and the other may be a drain. One of the first terminal S/D21 and the second terminal S/D22 of the second transistor T2 may be a source and the other may be a drain. Further, in FIG. 2, the description is made by taking both the first transistor T1 and the second transistor T2 being N-type transistors as an example, and the type of the transistors is not limited in practical application.

In addition, in combination with the description related to the circuit for reading and writing data in above some embodiments, the function of the first bit line BL1 in the memory is equivalent to the function of the above data signal line, the function of the second bit line BL2 is equivalent to the function of the above auxiliary signal line, the function of the first word line WL is equivalent to the function of the above first control signal line, and the function of the second word line WWL is equivalent to the function of the above second control signal line. For the structure configuration and use of the first bit line BL1, the second bit line BL2, the first word line WL, and the second word line WWL in the memory, the reference may be made to the circuit for reading and writing data in the above embodiments, which will not be described in detail here.

Some embodiments of the present disclosure further provide a method for driving a memory. The method is used for driving the memory as described above. Referring to FIG. 2, FIG. 5, FIG. 6, and FIG. 7, the method includes the following operations.

In the precharging stage tW1, the first bit line BL1 supplies the first reference voltage V1 to the first terminal S/D11 of the first transistor T1. The second bit line BL2 simultaneously supplies the first reference voltage V1 to both the second terminal S/D12 of the first transistor T1 and the second terminal S/D22 of the second transistor T1. The first word line WL applies the first write control voltage VCW1 to the second electrode B. The second word line WWL applies the third write control voltage VCW3 to the gate G2 of the second transistor T2 to control the second transistor T2 to be turned on, and thus to precharge the storage node SN. The first reference voltage V1 is greater than the sum of the maximum data voltage to be written in the memory cell U and the threshold voltage VTH of the first transistor T1.

In the data writing stage tW2, the second bit line BL2 is floated, and the first bit line BL1 supplies the data voltage Vdata to the first terminal S/D11 of the first transistor T1. The first transistor T1 is turned on, and when the storage node SN is discharged to a stable state, data corresponding to the data voltage is written.

In the data reading stage tR, the second word line WWL applies the fourth write control voltage VCW3 to the gate G2 of the second transistor T2, and the second transistor T2 is in an off state. The first word line WL applies the read control voltage VCR to the second electrode B. The second bit line BL2 simultaneously supplies the second reference voltage V2 to both the second terminal S/D12 of the first transistor T1 and the second terminal S/D22 of the second transistor T2. The first bit line BL1 reads the data written into the storage node SN in response to whether the first transistor T1 is turned on.

In some embodiments, referring to FIG. 6, the method further includes the following operation. In the data holding stage tW3, a voltage of the first bit line BL1 is pulled up to the first reference voltage V1, and after the voltage of the first bit line BL1 is the first reference voltage, the second transistor T2 is firstly turned off, and then a voltage of the second bit line BL2 is pulled up to the first reference voltage V1.

Further, continuing to refer to FIG. 6, after the second transistor T2 is turned off, the method further includes the following operation. The first word line WL applies the second write control voltage VCW2 to the second electrode B of the capacitor C. The second write control voltage VCW2 is less than the first write control voltage VCW1. Further, the difference between the second write control voltage VCW2 and the first write control voltage VCW1 may be reasonably set according to the requirements.

In some examples, continuing to refer to FIG. 6, in the data holding stage tW3, after the second transistor T2 is turned off, the voltage of the second bit line BL2 is firstly pulled up to the first reference voltage V1, or the second write control voltage VCW2 is firstly applied to the second electrode B of the capacitor C through the first word line WL, or these two operations are performed simultaneously.

In another embodiment, referring to FIG. 7, the method further includes the following operation. In the data holding stage tW3, the first word line WL firstly applies the second write control voltage VCW2 to the second electrode B of the capacitor C, and the voltage of the first bit line BL1 is pulled up to the first reference voltage V1, and then the second transistor T2 is turned off, and the voltage of the second bit line BL2 is pulled up to the first reference voltage V1. The second write control voltage VCW2 is less than the first write control voltage VCW1.

Here, it may be understood that the case that the second transistor T2 is turned off may be implemented by controlling a turn-off control voltage (that is, the fourth write control voltage VCW4) applied by the second word line WWL to the gate G2 of the second transistor T2.

It is to be understood that, in some embodiments, referring to FIG. 5, FIG. 6, and FIG. 7, the method further includes the following operation. In the first standby stage tD1 before the precharging stage tW1, and the second standby stage tD2 that is after the data holding stage tW3 and before the data reading stage tR, the first word line WL applies the second write control voltage VCW2 to the second electrode B of the capacitor C, the second word line WWL applies the fourth write control voltage VCW4 to the gate G2 of the second transistor T2, the first bit line BL1 supplies the first reference voltage V1 to the first terminal S/D11 of the first transistor T1, and the second bit line BL2 simultaneously supplies the first reference voltage V1 to both the second terminal S/D12 of the first transistor T1 and the second terminal S/D22 of the second transistor T2.

The technical principles of the driving methods mentioned in above some embodiments may be adaptively understood with reference to the technical principles of the above method for reading and writing data, which will not be described in detail here.

Some embodiments of the present disclosure further provide an electronic device, such as a data storage device, a photocopier, a network device, a household appliance, an instrument, a mobile phone, a computer, or a device having a data storage function. The electronic device may include a housing and a circuit board disposed within the housing, a memory integrated on the circuit board, or a data read/write circuit. The structure of the memory or the circuit for reading and writing data may refer to the related description in some embodiments described above. The electronic device may further include other necessary elements or components, which is not limited in the embodiments of the present disclosure.

In some embodiments, the memory may be coupled with an external control device such as a processor or an actuator. The processor is coupled to the memory, and the processor can control reading and writing operations of the memory.

In some embodiments, the memory is three-dimensional dynamic random-access memory.

The technical features of the above-described embodiments may be arbitrarily combined, and not all possible combinations of the technical features of the above-described embodiments have been described in order to make the description concise. However, as long as there is no contradiction in the combinations of these technical features, they should be considered to be within the scope of the present specification.

The above-described embodiments only describes several embodiments of the present disclosure, and the description thereof is relatively specific and detailed, but should not be construed as limiting the scope of the patent disclosure. It is to be pointed out that for those skilled in the art, several modifications and improvements may be made without departing from the concept of the present disclosure, which are all within the scope of protection of the present disclosure. Therefore, the scope of protection of the present disclosure is claimed in the appended claims.

1. A method for reading and writing data, applied to a memory cell, wherein the memory cell is configured to store data, and the memory cell comprises a capacitor, a first transistor and a second transistor that are connected with a first electrode of the capacitor; an intersection point where the first electrode, the first transistor and the second transistor are connected with each other is a storage node of the memory cell;
the capacitor further comprises a second electrode disposed opposite the first electrode, a data read-write period of the memory cell comprises: a precharging stage and a data writing stage, and the method for reading and writing data comprises:
in the precharging stage, supplying, by a data signal line, a first reference voltage to the first transistor, supplying simultaneously, by an auxiliary signal line, the first reference voltage to both the first transistor and second transistor; applying a first write control voltage to the second electrode of the capacitor, and turning on the second transistor to precharge the storage node, wherein a sum of a maximum data voltage corresponding to the data and a threshold voltage of the first transistor is a benchmark voltage, and the first reference voltage is greater than the benchmark voltage; and
in the data writing stage, in response to a write command, floating the auxiliary signal line, supplying, by the data signal line, a data voltage to the first transistor, and tuning on the first transistor; and when the storage node is discharged to a stable state, writing data corresponding to the data voltage into the storage node.

2. The method for reading and writing data of claim 1, wherein the data read-write period further comprises: a data holding stage after the data writing stage, and the method for reading and writing data further comprises:
in the data holding stage, pulling up a voltage of the data signal line to the first reference voltage, and after the voltage of the data signal line is the first reference voltage, firstly turning off the second transistor, and then pulling up a voltage of the auxiliary signal
wherein after the second transistor is turned off, the method for reading and writing data further comprises: applying a second write control voltage to the second electrode of the capacitor, wherein the second write control voltage is less than the first write control voltage.

3. The method for reading and writing data of claim 1, wherein the data read-write period further comprises: a data holding stage after the data writing stage, and the method for reading and writing data further comprises:
in the data holding stage, firstly applying a second write control voltage to the second electrode of the capacitor, and pulling up a voltage of the data signal line to the first reference voltage; and then turning off the second transistor, and pulling up a voltage of the auxiliary signal line to the first reference voltage, wherein the second write control voltage is less than the first write control voltage.

4. The method for reading and writing data of claim 1, wherein the data read-write period further comprises: a data reading stage, and the method for reading and writing data further comprises:
in the data reading stage, in response to a read command, applying a read control voltage to the second electrode of the capacitor, and supplying simultaneously, by the auxiliary signal line, a second reference voltage to both the first transistor and second transistor, wherein the data signal line reads data in response to whether the first transistor is turned on.

5. The method for reading and writing data of claim 1, wherein data written into the storage node comprises “1” or “0”, and in a data reading stage, when the data written into the storage node is “1”, the first transistor is in an on state, and when the data written into the storage node is “0”, the first transistor is in an off state.

6. The method for reading and writing data of claim 1, wherein the data read-write period further comprises: a standby stage before the precharging stage and/or before a data reading stage, and the method for reading and writing data further comprises:
in the standby stage, the first transistor and the second transistor being in an off state, supplying, by the data signal line, the first reference voltage to the first transistor, and supplying simultaneously, by the auxiliary signal line, the first reference voltage to both the first transistor and the second transistor.

7. The method for reading and writing data of claim 6, wherein the data read-write period further comprises: a data holding stage after the data writing stage, and the data reading stage is after the data holding stage; and
the standby stage comprises a first standby stage before the precharging stage, and a second standby stage that is after the data holding stage and before the data reading stage.

8. A circuit for reading and writing data, comprising:
a memory cell, configured to store data, and comprising a capacitor, and a first transistor and a second transistor that are connected with a first electrode of the capacitor, wherein the capacitor further comprises a second electrode disposed opposite the first electrode, and an intersection point where the first electrode, the first transistor and the second transistor are connected with each other is a storage node of the memory cell;
a data signal line, connected with the first transistor, and configured to: supply a first reference voltage to the first transistor in a standby stage and a precharging stage;
supply a data voltage to the first transistor in a data writing stage; and read data in response to whether the first transistor is turned on in a data reading stage; and
an auxiliary signal line, connected with the first transistor and the second transistor, and configured to: supply the first reference voltage to the first transistor in the standby stage and the precharging stage; be floated in the data writing stage; and simultaneously supply a second reference voltage to both the first transistor and the second transistor in the data reading stage;
wherein a sum of a maximum data voltage corresponding to the data and a threshold voltage of the first transistor is a benchmark voltage, and the first reference voltage is greater than the benchmark voltage.

9. The circuit for reading and writing data of claim 8, further comprising:
a first control signal line, connected with the second electrode of the capacitor, and configured to: apply a first write control voltage to the second electrode in the precharging stage and the data writing stage; and apply a read control voltage to the second electrode in the data reading stage; and
a second control signal line, connected with the second transistor, and configured to: control the second transistor to be turned off in the standby stage and the data reading stage; and control the second transistor to be turned on in the precharging stage and the data writing stage.

10. The circuit for reading and writing data of claim 9, wherein
the data signal line is further configured to: in a data holding stage, supply the first reference voltage to the first transistor;
the second control signal line is further configured to: in the data holding stage, control the second transistor to be turned off after the voltage of the data signal line is the first reference voltage;
the auxiliary signal line is further configured to: in the data holding stage, simultaneously supply the first reference voltage to both the first transistor and the second transistor after the second transistor is turned off; and
the first control signal line is further configured to: in the data holding stage, apply a second write control voltage to the second electrode after the second transistor is turned off, wherein the second write control voltage is less than the first write control voltage.

11. The circuit for reading and writing data of claim 9, wherein
the first control signal line is further configured to: in a data holding stage, apply a second write control voltage to the second electrode, wherein the second write control voltage is less than the first write control voltage;
the data signal line is further configured to: in the data holding stage, supply the first reference voltage to the first transistor after a voltage of the second electrode is the second write control voltage;
the second control signal line is further configured to: in the data holding stage, control the second transistor to be turned off after the data signal line supplies the first reference voltage; and
the auxiliary signal line is further configured to: in the data holding stage, supply the first reference voltage to both the first transistor and the second transistor after the second transistor is turned off.

12. The circuit for reading and writing data of claim 9, wherein the first transistor comprises a first gate, a first terminal, and a second terminal, and the second transistor comprises a second gate, a first terminal, and a second terminal; wherein,
the first gate and the first terminal of the second transistor are both connected with the first electrode;
the second electrode is connected with the first control signal line;
the second gate is connected with the second control signal line;
the first terminal of the first transistor is connected with the data signal line; and
the second terminal of the first transistor and the second terminal of the second transistor are connected with the auxiliary signal line, respectively.

13. The circuit for reading and writing data of any one of claim 9, wherein a plurality of memory cells exist, the plurality of the memory cells are arranged in rows along a first direction and arranged in columns along a second direction, and the first direction intersects with the second direction; and
wherein memory cells in one row share one first control signal line and one second control signal line, and
memory cells in one column share one data signal line and one auxiliary signal line.

14. The circuit for reading and writing data of claim 8, further comprising:
a first reference voltage terminal, connected to the data signal line through a first gating circuit and connected to the auxiliary signal line through a second gating circuit, wherein the first reference voltage terminal is configured to supply the first reference voltage, the first gating circuit is configured to selectively connect the first reference voltage terminal and the data signal line in the standby stage and the precharging stage, and the second gating circuit is configured to selectively connect the first reference voltage terminal and the auxiliary signal line in the standby stage and the precharging stage; and
a second reference voltage terminal, connected to the auxiliary signal line through a third gating circuit, wherein the second reference voltage terminal is configured to supply the second reference voltage, and the third gating circuit is configured to selectively connect the second reference voltage terminal and the auxiliary signal line in the data reading stage.

15. A memory, comprising: at least one memory cell, and at least one first bit line, at least one second bit line, at least one first word line, and at least one second word line that are correspondingly connected to the at least one memory cell;
wherein each of the at least one memory cell comprises a capacitor, a first transistor, and a second transistor, the capacitor comprises a first electrode and a second electrode that are insulated, and each of the first transistor and the second transistor comprises a gate, a first terminal and a second terminal;
the first electrode, the gate of the first transistor and the first terminal of the second transistor are connected with each other, and an intersection point where the first electrode, the gate of the first transistor and the first terminal of the second transistor are connected with each other is a storage node;
the first word line is connected with the second electrode, and the second word line is connected with the gate of the second transistor; and
the first bit line is connected with the first terminal of the first transistor, and the second bit line is connected to both the second terminal of the first transistor and the second terminal of the second transistor;
wherein the first bit line is configured to: supply a first reference voltage to the first terminal of the first transistor in a precharging stage; supply a data voltage of data to be written to the first transistor in a data writing stage; and read data written into the storage node in response to whether the first transistor is turned on in a data reading stage; and
the second bit line is configured to: supply simultaneously the first reference voltage to both the second terminal of the first transistor and the second terminal of the second transistor in the precharging stage; be floated in the data writing stage; and supply simultaneously a second reference voltage to both the first transistor and the second transistor in the data reading stage;
wherein the first reference voltage is greater than a sum of a maximum data voltage to be written in the at least one memory cell and a threshold voltage of the first transistor.

16. A method for driving a memory, applied to the memory of claim 15, comprising:
in the precharging stage, supplying, by the first bit line, the first reference voltage to the first terminal of the first transistor, supplying simultaneously, by the second bit line, the first reference voltage to both the second terminal of the first transistor and the second terminal of the second transistor; applying, by the first word line, a first write control voltage to the second electrode, and applying, by the second word line, a third write control voltage to the gate of the second transistor to control the second transistor to be turned on, so as to precharge the storage node;
in the data writing stage, floating the second bit line, supplying, by the first bit line, a data voltage to the first terminal of the first transistor; and turning on the first transistor, and when the storage node is discharged to a stable state, writing data corresponding to the data voltage into the storage node; and
in the data reading stage, applying, by the second word line, a fourth write control voltage to the gate of the second transistor, the second transistor being in an off state;
applying, by the first word line, a read control voltage to the second electrode; supplying simultaneously, by the second bit line, the second reference voltage to both the second terminal of the first transistor and the second terminal of the second transistor; reading, by the data signal line, the data written into the storage node in response to whether the first transistor is turned on;
wherein the first reference voltage is greater than a sum of a maximum data voltage to be written into the at least one memory cell and a threshold voltage of the first transistor.

17. (canceled)

18. The method of claim 16, further comprising:
in a data holding stage, pulling up a voltage of the first bit line to the first reference voltage, and after the voltage of the first bit line is the first reference voltage, firstly turning off the second transistor first, and then pulling up a voltage of the second bit line to the first reference voltage;
wherein after the second transistor is turned off, the method further comprises: applying, by the first word line, a second write control voltage to the second electrode of the capacitor, wherein the second write control voltage is less than the first write control voltage.

19. The method of claim 16, further comprising:
in the data holding stage, firstly applying, by the first word line, a second write control voltage to the second electrode of the capacitor, and pulling up a voltage of the data signal line to the first reference voltage; and then turning off the second transistor, and pulling up a voltage of the first bit line to the first reference voltage; and then pulling up a voltage of the second bit line to the first reference voltage, wherein the second write control voltage is less than the first write control voltage.
